(19) United States
(12) Patent Application Publication
(10) Pub. No.: US 2018/0035534 A1
(43) Pub. Date: Feb. 1, 2018

(54) PRINTED WIRING BOARD AND METHOD FOR MANUFACTURING SAME

(71) Applicant: IBIDEN CO., LTD., Ogaki (JP)

(72) Inventors: Hirotaka TANIGUCHI, Ogaki (JP); Ryuzo NISHIKAWA, Ogaki (JP); Haruhiko MORITA, Ogaki (JP)

(73) Assignee: IBIDEN CO., LTD., Ogaki (JP)

(21) Appl. No.: 15/661,107

(22) Filed: Jul. 27, 2017

(30) Foreign Application Priority Data
Jul. 27, 2016 (JP) 2016-147526

(51) Int. Cl. H05K 1/02; H05K 3/02; H05K 3/46

(52) U.S. Cl. CPC H05K 1/0242; H05K 1/0298; H05K 3/46; H05K 3/02

(57) ABSTRACT

A printed wiring board includes a base substrate, a first insulative resin layer laminated on first surface of the base substrate, and a first conductive layer laminated on the first insulative resin layer. The base substrate includes conductive layers and insulative resin layers, the base substrate, first insulative resin layer and first conductive layer include a high-frequency substrate portion including portion of an outermost conductive layer in the base substrate, portion of the first insulative resin layer and portion of the first conductive layer, the first conductive layer has wiring patterns including microstrip lines and the portion forming the high-frequency substrate portion, the first insulative resin layer has dielectric constant of 3.5 or lower and dielectric loss tangent of 0.005 or lower, and the wiring pattern is formed such that side surfaces of the wiring pattern are substantially parallel to a thickness direction of the first insulative resin layer.

### CROSS-REFERENCE TO RELATED APPLICATIONS

The present application is based upon and claims the benefit of priority to Japanese Patent Application No. 2016-147526, filed Jul. 27, 2016, the entire contents of which are incorporated herein by reference.

### BACKGROUND OF THE INVENTION

### Field of the Invention

The present invention relates to a printed wiring board having a microstripline and a method for manufacturing such a wiring board.

### Description of Background Art

JP H08-181458A describes a printed wiring board, in which a wiring pattern for a microstripline is formed on an insulation layer made of a low dielectric resin material. In such a printed wiring board, the wiring pattern is formed by etching a metal layer laminated on an insulation layer. The entire contents of this publication are incorporated herein by reference.

### SUMMARY OF THE INVENTION

According to one aspect of the present invention, a printed wiring board includes a base substrate, a first insulative resin layer laminated on a first surface of the base substrate, and a first conductive layer laminated on the first insulative resin layer. The base substrate includes conductive layers and insulative resin layers, the base substrate, the first insulative resin layer and the first conductive layer include a high-frequency substrate portion including a portion of an outermost conductive layer in the base substrate, a portion of the first insulative resin layer and a portion of the first conductive layer, the first conductive layer has wiring patterns including microstrip lines and the portion forming the high-frequency substrate portion, the first insulative resin layer has a dielectric constant of 3.5 or lower and a dielectric loss tangent of 0.005 or lower, and the wiring pattern is formed such that side surfaces of the wiring pattern are substantially parallel to a thickness direction of the first insulative resin layer.

According to another aspect of the present invention, a method for manufacturing a printed wiring board includes forming a base substrate including conductive layers and insulative resin layers alternately laminated, laminating a first insulative resin layer on a first surface of the base substrate, and forming a first conductive layer on the first insulative resin layer. The forming of the base substrate, the laminating of the first insulative resin layer and the forming of the first conductive layer include forming a high-frequency substrate portion including a portion of an outermost conductive layer in the base substrate, a portion of the first insulative resin layer and a portion of the first conductive layer, and the forming of the first conductive layer includes laminating laminating a metal foil entirely on the first insulative resin layer, forming a plated layer having a pattern on the metal foil, and removing the metal foil from where no plated layer is formed such that the first conductive layer includes wiring patterns including microstrip lines and the portion forming the high-frequency substrate portion.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a printed wiring board;

FIG. 2 is an enlarged view near the first conductive layer shown in FIG. 1;

FIG. 3A to FIG. 3C are cross-sectional views showing manufacturing processes of a printed wiring board;

FIG. 4A to FIG. 4C are cross-sectional views showing manufacturing processes of the printed wiring board;

FIG. 5A and FIG. 5B are cross-sectional views showing manufacturing processes of the printed wiring board;

FIG. 6A and FIG. 6B are cross-sectional views showing manufacturing processes of the printed wiring board;

FIG. 7A and FIG. 7B are cross-sectional views showing manufacturing processes of the printed wiring board;

FIG. 8 is a cross-sectional view showing a manufacturing process of the printed wiring board;

FIG. 9 is a cross-sectional view showing a manufacturing process of the printed wiring board;

FIG. 10 is a cross-sectional view showing a manufacturing process of the printed wiring board;

FIG. 11 is a cross-sectional view showing a manufacturing process of the printed wiring board;

FIG. 12 is a cross-sectional view showing a manufacturing process of the printed wiring board;

FIG. 13 is a cross-sectional view showing a manufacturing process of the printed wiring board;

FIG. 14 is a cross-sectional view showing a manufacturing process of the printed wiring board;

FIG. 15 is a cross-sectional view showing a manufacturing process of the printed wiring board;

FIG. 16 is a cross-sectional view showing a manufacturing process of the printed wiring board;

FIG. 17A is a cross-sectional view of a substrate related to test example 1;

FIG. 17B is a cross sectional view of a substrate related to test example 2; and

FIG. 18 is a graph showing frequency characteristics of insertion loss at wiring patterns in each of the test examples.

### DETAILED DESCRIPTION OF THE EMBODIMENTS

Embodiments will now be described with reference to the accompanying drawings, wherein like reference numerals designate corresponding or identical elements throughout the various drawings.

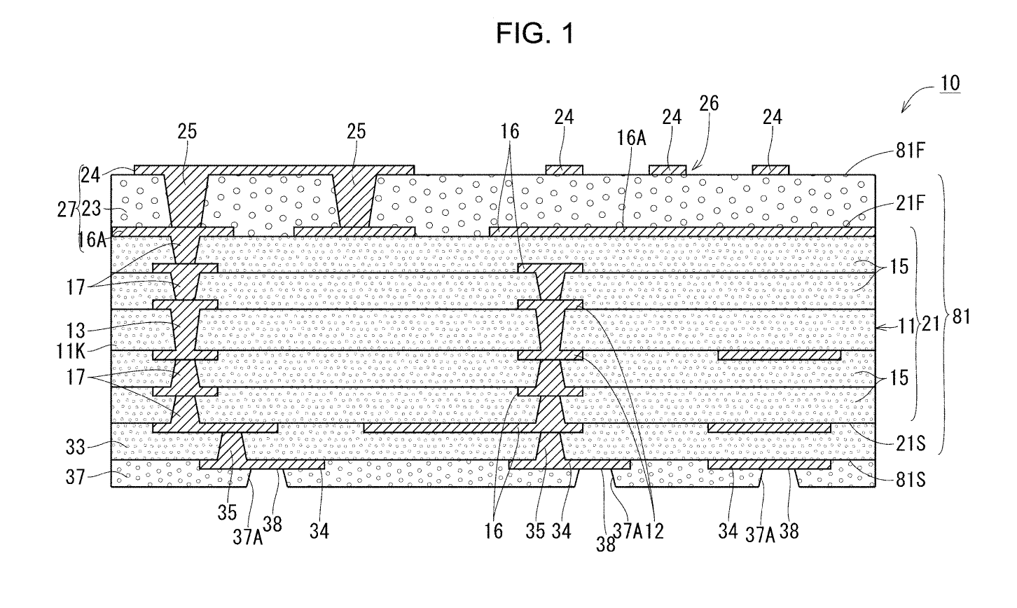

In the following, an embodiment of the present invention is described by referring to FIG. 1˜18. As shown in FIG. 1, printed wiring board 10 according to the present embodiment has substrate 81 having first surface (81F) and second surface (81S) as its upper and lower surfaces respectively, where first conductive layer 24 is laminated on first surface (81F) and second conductive layer 34 is laminated on second surface (81S). Substrate 81 is formed with base substrate portion 21 having third surface (21F) and fourth surface (21S) as its upper and lower surfaces respectively, first insulative resin layer 23 laminated on third surface (21F), and second insulative resin layer 33 laminated on fourth surface (21S).

Printed wiring board 10 has solder-resist layer 37 only on the second-surface (81S) side of substrate 81. Solder-resist layer 37 is laminated on second conductive layer 34. Openings (37A) are formed in solder-resist layer 37. Pads 38 are formed using second conductive layer 34 positioned inside openings (37A).

Base substrate portion 21 is formed by alternately laminating interlayer insulative resin layer 15 and conductive layer 16 on the upper and lower sides of core substrate 11. Core substrate 11 is formed by laminating conductive layer 12 on the upper and lower sides of insulative base material (11K). Insulative base material (11K) is made of prepreg obtained by impregnating a core material such as glass fiber with a resin containing inorganic filler. Upper-side conductive layer 12 and lower-side conductive layer 12 are connected by via conductors 13 penetrating through insulative base material (11K).

Multiple interlayer insulative resin layers 15 and multiple conductive layers 16 are formed on both the upper and lower sides of core substrate 11. In a thickness direction of base substrate portion 21, conductive layers 16 sandwiching an interlayer insulative resin layer 15 are connected by via conductors 17 penetrating through the interlayer insulative resin layer 15. In addition, conductive layer 16 closest to core substrate 11 is connected to conductive layer 12 of core substrate 11 by via conductors 17 penetrating through the interlayer insulative resin layer 15 formed directly on core substrate 11. Interlayer insulative resin layers 15 may be made of the same prepreg as that of insulative base material (11K), or may be made of a resin film that does not include a core material but contains inorganic filler. In the present embodiment, insulative base material (11K) and interlayer insulative resin layers 15 each correspond to an “insulative resin layer” related to the present invention.

First insulative resin layer 23 forms first surface (81F) of substrate 81, and first conductive layer 24 is laminated on first insulative resin layer 23. First conductive layer 24 is connected to conductive layer 16 exposed on third surface (21F) of base substrate portion 21 by via conductors 25 penetrating through first insulative resin layer 23.

Second insulative resin layer 33 forms second surface (81S) of substrate 81, and second conductive layer 34 is laminated on second insulative resin layer 33. Second conductive layer 34 is connected to conductive layer 16 exposed on fourth surface (21S) of base substrate portion 21 by via conductors 35 penetrating through second insulative resin layer 33.

The thickness of first insulative resin layer 23 is set greater than that of second insulative resin layer 33. The thickness of second insulative resin layer 33 is set to be approximately the same as that of interlayer insulative resin layer 15 of base substrate portion 21. In an example of the present embodiment, the thickness of first insulative resin layer 23 is 100˜200 μm, and the thicknesses of second insulative resin layer 33 and interlayer insulative resin layers 15 are each 40˜100 μm. Thicknesses of first conductive layer 24, second conductive layer 34 and conductive layers 16 of base substrate portion 21 are each 15˜35 μm. The thickness of insulative base material (11K) of core substrate 11 is 40˜600 μm, preferably 40˜100 μm.

First insulative resin layer 23 is made of a material having greater high frequency characteristics than the material of second insulative resin layer 33. Dielectric constant (Dk) of first insulative resin layer 23 is set lower than dielectric constant (Dk) of second insulative resin layer 33, while dielectric loss tangent (Df) of first insulative resin layer 23 is set lower than dielectric loss tangent (Df) of second insulative resin layer 33. More specifically, first insulative resin layer 23 has a dielectric constant (Dk) of 3.0˜3.5 and a dielectric loss tangent (Df) of 0.001˜0.005, while second insulative resin layer 33 has a dielectric constant (Dk) of 4.1, for example, and a dielectric loss tangent (Df) of 0.012, for example. As for the material to foil ii first insulative resin layer 23, low dielectric constant materials such as liquid-crystal polymers and PTFE may be used. Second insulative resin layer 33 is made of the same material as that for interlayer insulative resin layers 15 of base substrate portion 21.

As shown in FIG. 1, on the first-surface (81F) side of substrate 81, printed wiring board 10 has high-frequency substrate portion 27 that includes high-frequency wiring patterns. High-frequency substrate portion 27 has conductive layer (16A) positioned outermost on the first-surface (81F) side of substrate 81 (hereinafter referred to as “outermost conductive layer (16A)”), first insulative resin layer 23, and first conductive layer 24. In high-frequency substrate portion 27, microstripline 26 is formed with outermost conductive layer (16A) and first conductive layer 24. Outermost conductive layer (16A) works as the ground layer of microstripline 26 while first conductive layer 24 makes wiring patterns of microstripline 26.

The minimum width of wiring patterns forming by first conductive layer 24 is at least 75 μm. In addition, the minimum value of distances between adjacent wiring patterns is at least 75 μm in high-frequency substrate portion 27.

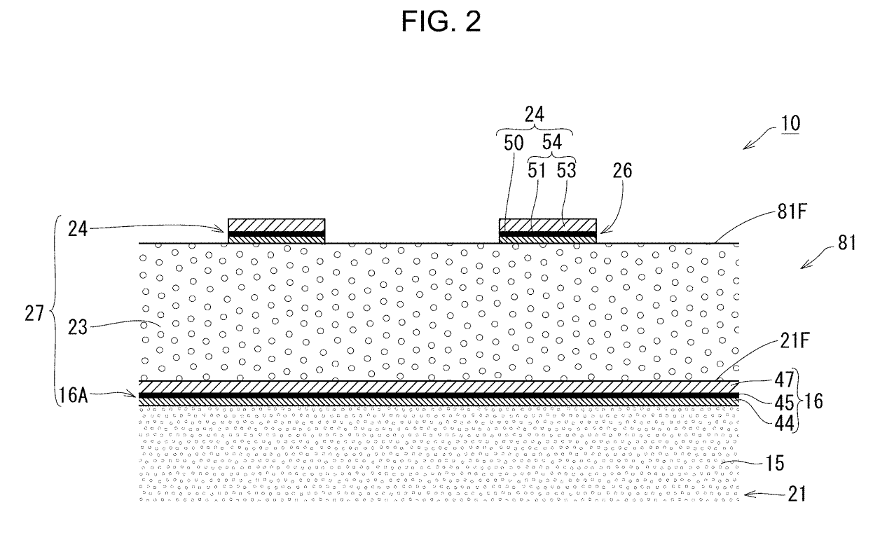

As shown in FIG. 2, first conductive layer 24 is made up of copper foil 50 and plated layer 54 laminated on copper foil 50. Plated layer 54 is double-structured with electroless plated film 51 and electrolytic plated film 53. The thickness of copper foil 50 is 5 μm or less.

Side surfaces of first conductive layer 24 are each set to be substantially vertical to first surface (81F) of substrate 81 and substantially parallel to the thickness direction of substrate 81. Also, among surfaces of first conductive layer 24, the upper surface opposite substrate 81 and side surfaces are made smooth. Roughness (Ra) (arithmetic mean roughness) of the interface between first conductive layer 24 and first insulative resin layer 23 of wiring board 10 is set smaller than 0.5 μm.

Printed wiring board 10 of the present embodiment is manufactured as follows.

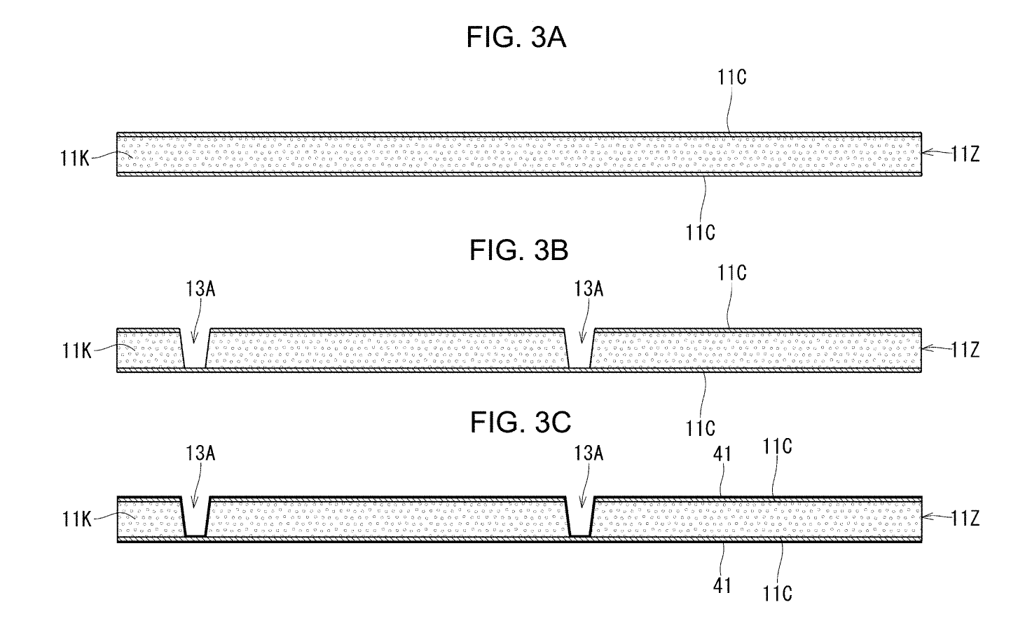

(1) As shown in FIG. 3A, copper-clad laminate (11Z), where copper foil (11C) is laminated on both of the upper and lower sides of insulative base material (11K), is prepared.

(2) As shown in FIG. 3B, tapered holes (13A) are pierced by irradiating either of the upper and lower sides of copper-clad laminate (11Z) with a CO₂ laser, for example. Tapered holes (13A) are non-penetrating holes having their bottoms at copper-foil (11C), which is positioned on the other side of the upper and lower sides of copper-clad laminate (11Z).

(3) As shown in FIG. 3C, electroless plating treatment is conducted to form electroless plated film 41 on copper foil (11C) and on the inner surfaces of tapered holes (13A).

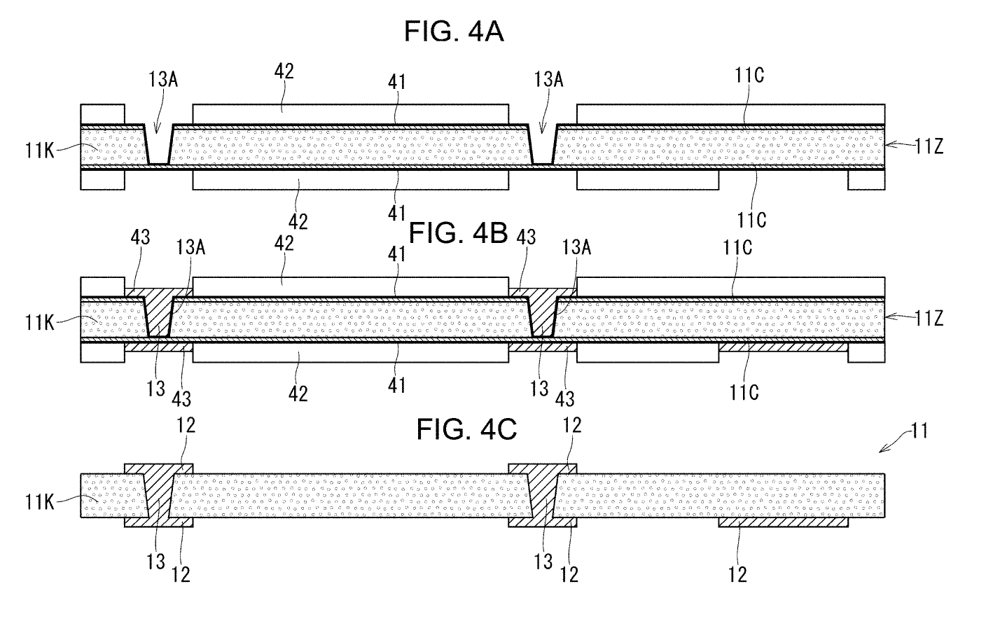

(4) As shown in FIG. 4A, plating resist 42 with a predetermined pattern is formed on electroless plated film 41.

Electrolytic plating treatment is conducted. As shown in FIG. 4B, electrolytic plating is filled in tapered holes (13A) to form via conductors 13 while electrolytic plated film 43 is formed on portions of electroless plated film 41 on copper foil (11C) that are exposed from plating resist 42.

(6) When plating resist 42 is peeled off, electroless plated film 41 and copper foil (11C) positioned under plating resist 42 are also removed. Accordingly, as shown in FIG. 4C, remaining electrolytic plated film 43, electroless plated film 41 and copper foil (11C) form conductive layer 12 on each of both the upper and lower sides of insulative base material (11K). Then, upper-side conductive layer 12 and lower-side conductive layer 12 are connected by via conductors 13, and core substrate 11 is obtained.

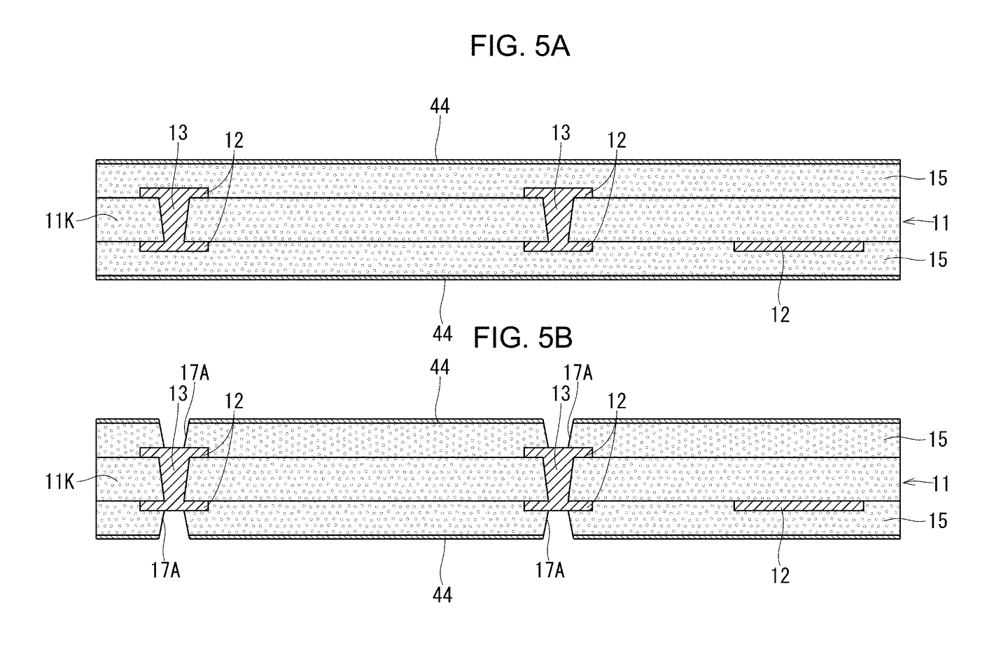

(7) As shown in FIG. 5A, on conductive layer 12 of core substrate 11, prepreg is laminated as interlayer insulative resin layers 15, on which copper foil 44 is further laminated. Then, the laminate is heat-pressed. During that time, the space between portions of conductive layers (12, 12) is filled with the prepreg.

(8) As shown in FIG. 5B, a laser is irradiated on interlayer insulative resin layer 15 from both sides of core substrate 11 to form via holes (17A).

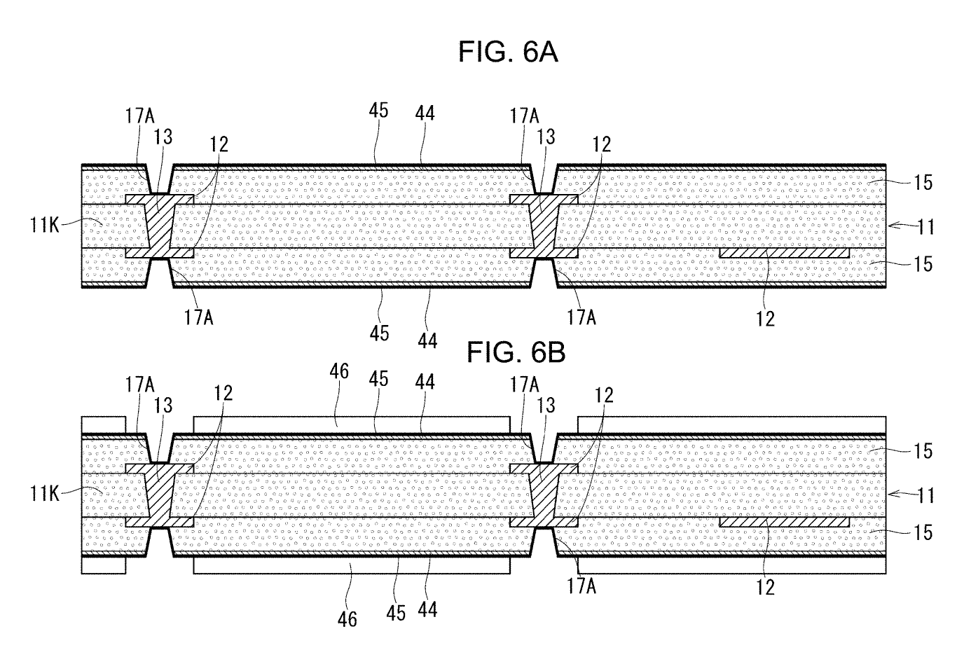

(9) Electroless plating treatment is conducted to form electroless plated film 45 on interlayer insulative resin layer 15 and on the inner surfaces of via holes (17A) (see FIG. 6A).

(10) As shown in FIG. 6B, plating resist 46 with a predetermined pattern is formed on electroless plated film 45.

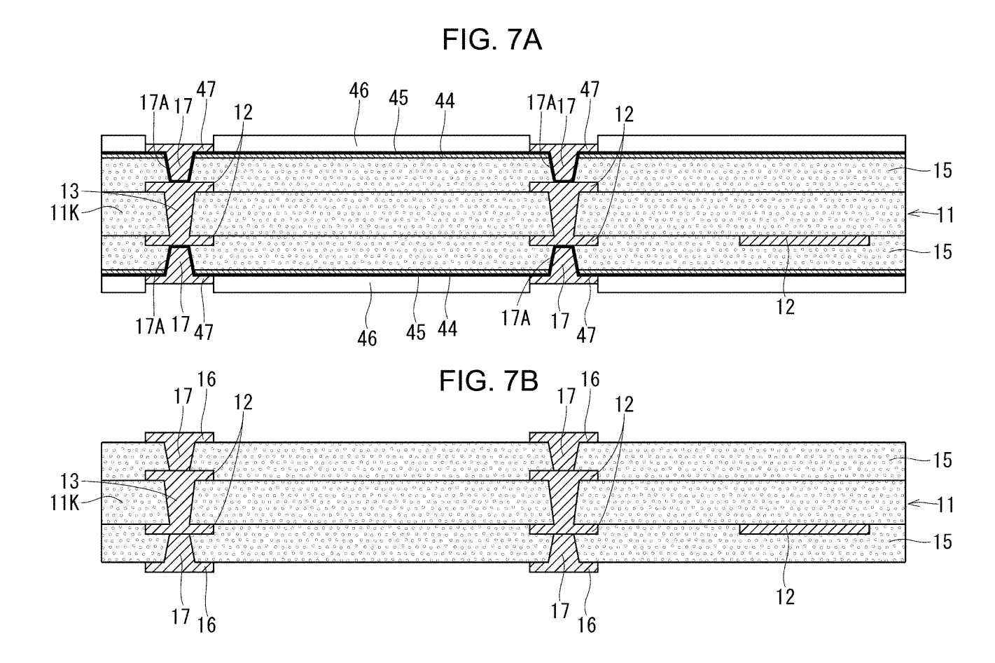

(11) Electrolytic plating treatment is conducted. As shown in FIG. 7A, electrolytic plating is filled in via holes (17A) to form via conductors 17, and electrolytic plated film 47 is formed on portions of electroless plated film 45 that are exposed from plating resist 46.

(12) As shown in FIG. 7B, plating resist 46 is peeled off, and electroless plated film 45 and copper foil 44 positioned under plating resist 46 are removed. Remaining electrolytic plated film 47, electroless plated film 45 and copper foil 44 form conductive layer 16 on interlayer insulative resin layer 15. Then, conductive layer 12 and conductive layer 16 are connected by via conductors 17.

Instead of using prepreg, interlayer insulative resin layer 15 may also be formed using resin film that does not contain a core material but contains inorganic filler. In such a case, without laminating copper foil 44, conductive layer 16 is directly formed on the resin film by a semi-additive method.

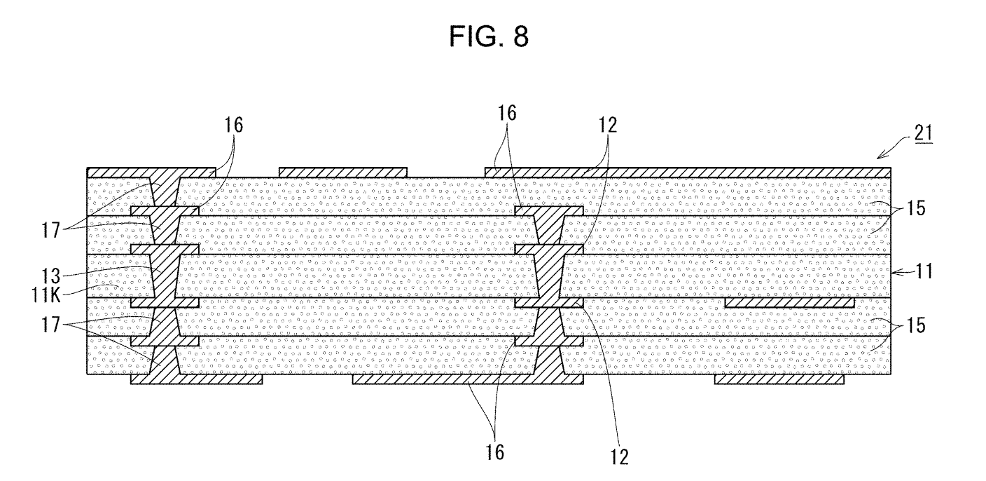

(13) The same procedures as in processes described in (7)˜(12) above are repeated so that multiple interlayer insulative resin layers 15 and multiple conductive layers 16 are alternately laminated on both the upper and lower sides of core substrate 11 as shown in FIG. 8. Accordingly, base substrate portion 21 of printed wiring board 10 is formed. Conductive layers (16, 16) sandwiching an interlayer insulative resin layer 15 are connected by via conductors 17 penetrating through the interlayer insulative resin layer 15.

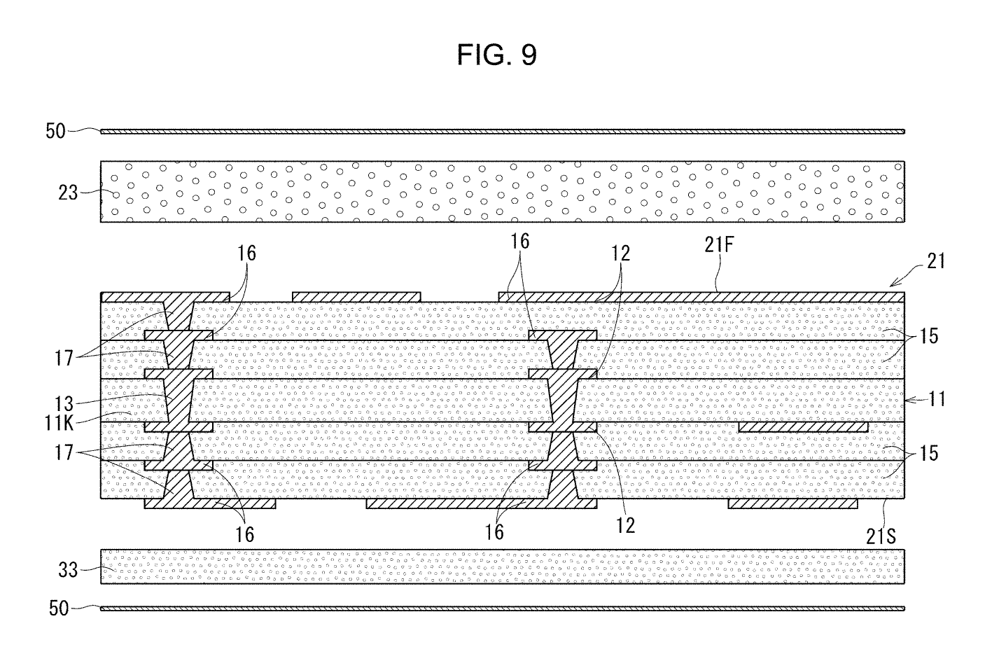

(14) As shown in FIG. 9, a sheet made of a low dielectric constant material as first insulative resin layer 23 and copper foil 50 are placed in that order on the first-surface (81F) side of base substrate portion 21, while prepreg as second insulative resin layer 33 and copper foil 50 are placed in that order on the second-surface (81S) side of base substrate portion 21. Here, horizontal positions of base substrate portion 21, first insulative resin layer 23, second insulative resin layer 33 and copper foils 50 are determined based on the alignment marks respectively formed in advance on base substrate portion 21, first insulative resin layer 23, second insulative resin layer 33 and copper foils 50.

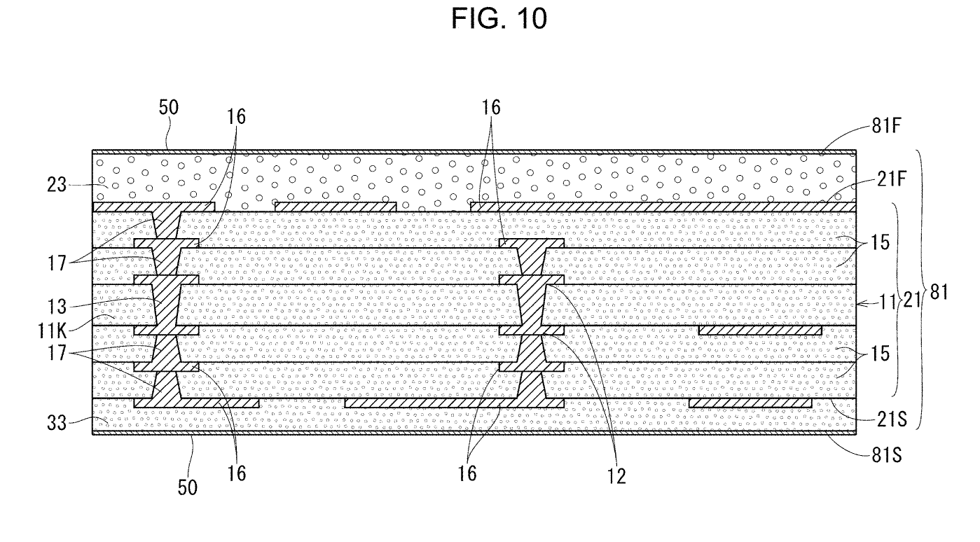

(15) Heat-pressing is conducted so that first insulative resin layer 23 and copper foil 50 are laminated in that order on third surface (21F) of base substrate portion 21, while second insulative resin layer 33 and copper foil 50 are laminated in that order on fourth surface (21S) of base substrate portion 21 (see FIG. 10). During that time, the space between portions of conductive layer 16 exposed on third surface (21F) of base substrate portion 21 is filled with the low dielectric constant material of first insulative resin layer 23, while the space between portions of conductive layer 16 exposed on fourth surface (21S) of base substrate portion 21 is filled with prepreg of second insulative resin layer 33. Substrate 81 is formed to have base substrate portion 21, first insulative resin layer 23 and second insulative resin layer 33.

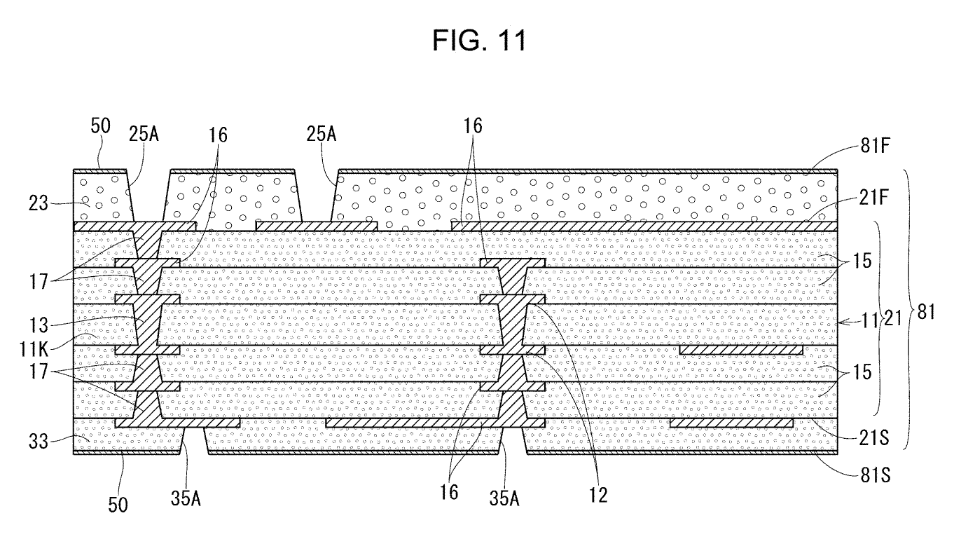

(16) As shown in FIG. 11, a laser is irradiated from the first-surface (81F) side of substrate 81 so as to form via holes (25A) that penetrate through first insulative resin layer 23 and copper foil 50. Also, a laser is irradiated from the second-surface (81S) side of substrate 81 so as to form via holes (35A) that penetrate through second insulative resin layer 33 and copper foil 50.

(17) Roughening treatment is conducted on the upper and lower sides of substrate 81. More specifically, roughening treatment is conducted so that first surface (81F) of substrate 81 is set to have a roughness of 0.5 μm or smaller.

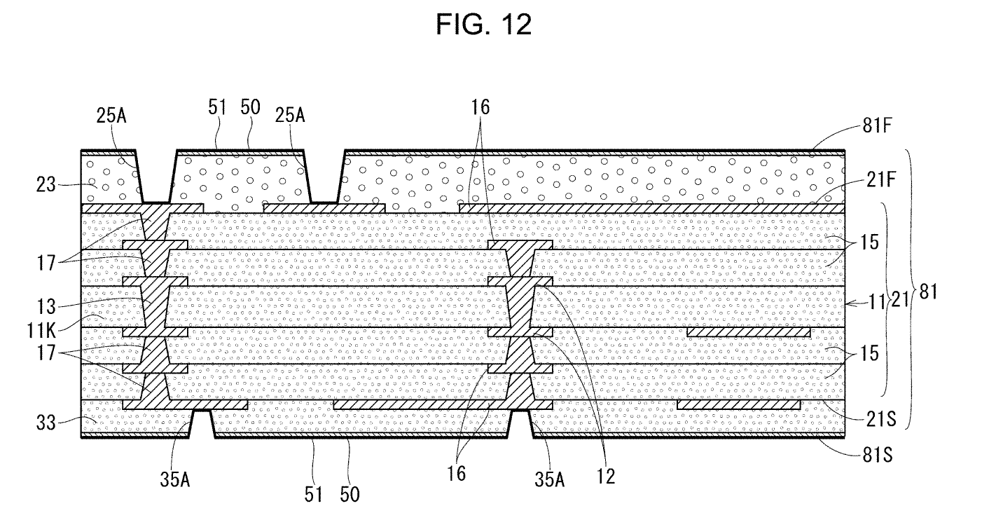

(18) Electroless plating treatment is conducted. As shown in FIG. 12, electroless plated film 51 is formed on copper foil 50 and on the inner surfaces of via holes (25A) on the first-surface (81F) side of substrate 81, while electroless plated film 51 is formed on copper foil 50 and on the inner surfaces of via holes (35A) on the second-surface (81S) side of substrate 81.

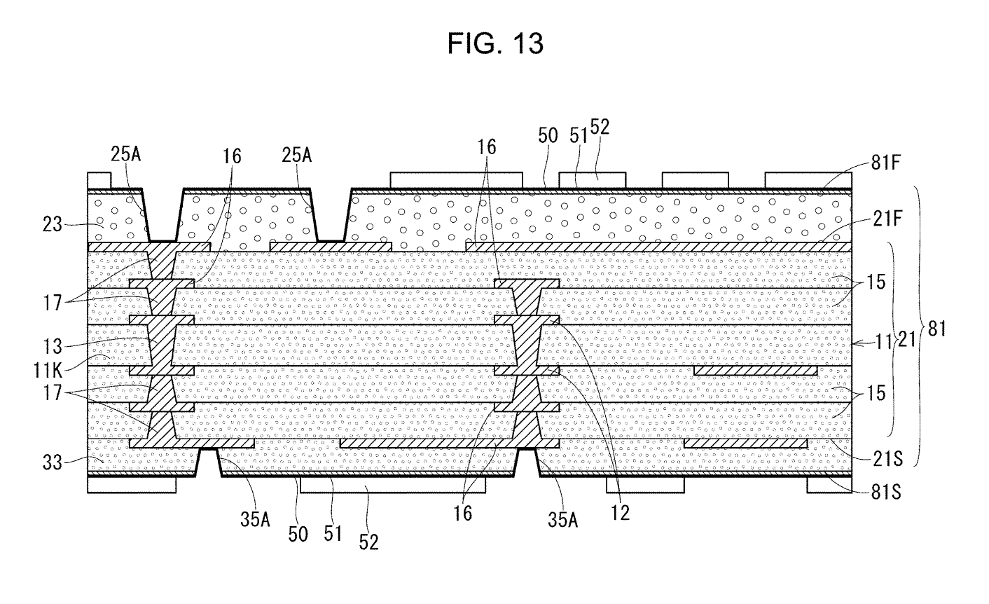

(19) As shown in FIG. 13, plating resist 52 with a predetermined pattern is formed on electroless plated film 51.

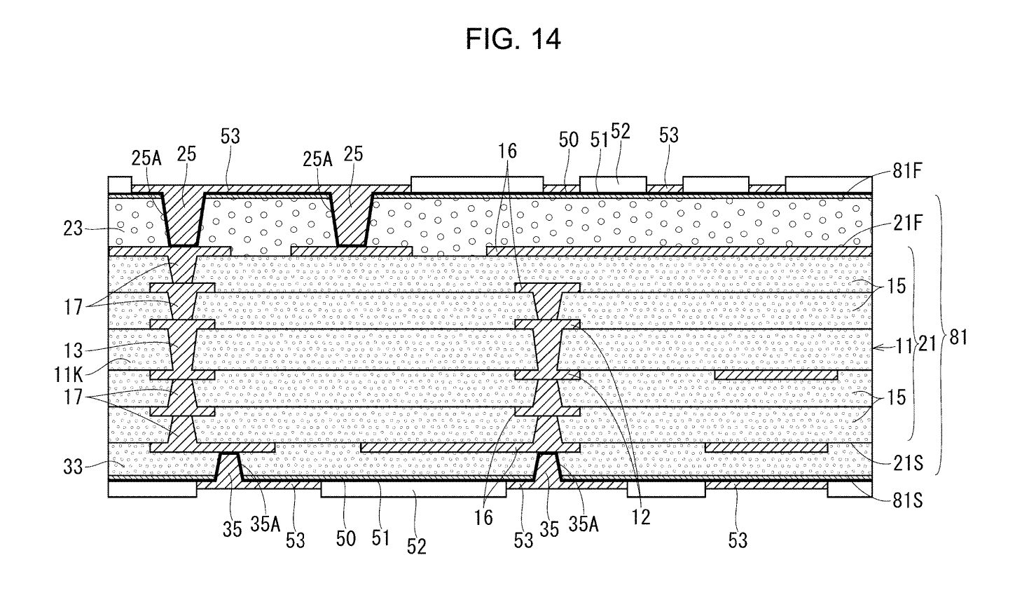

(20) Electrolytic plating treatment is conducted. As shown in FIG. 14, on the first-surface (81F) side of substrate 81, electrolytic plating is filled in via holes (25A) to foul′ via conductors 25, and electrolytic plated film 53 is formed on portions of electroless plated film 51 that are exposed from plating resist 52, while on the second-surface (81S) side of substrate 81, electrolytic plating is filled in via holes (35A) to form via conductors 35, and electrolytic plated film 53 is formed on portions of electroless plated film 51 that are exposed from plating resist 52.

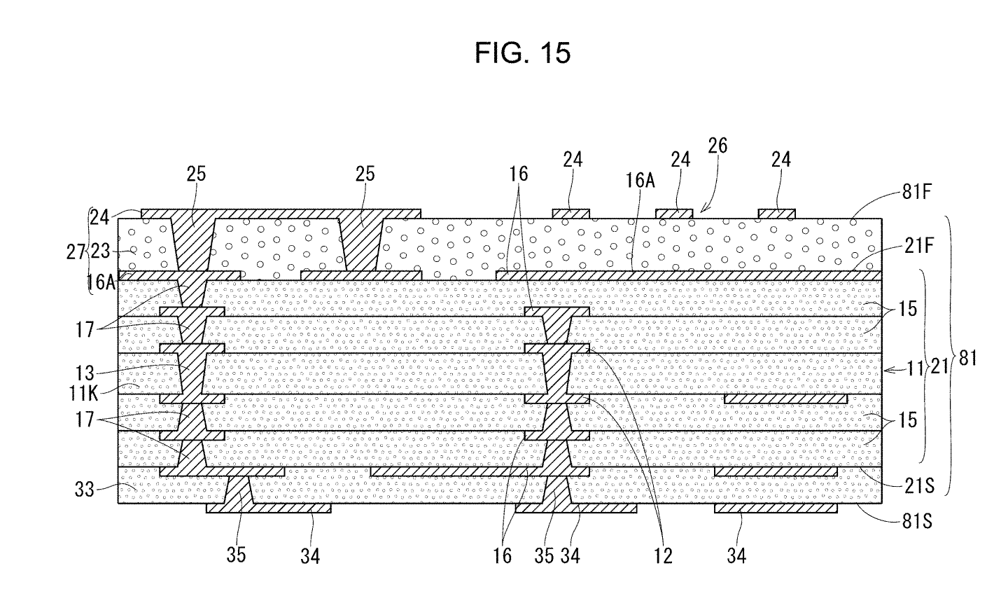

(21) Plating resist 52 is peeled off, and electroless plated film 51 and copper foil 50 positioned under plating resist 52 are etched away. Accordingly, as shown in FIG. 15, remaining electrolytic plated film 53, electroless plated film 51 and copper foil 50 form first conductive layer 24 on first insulative resin layer 23 while forming second conductive layer 34 on second insulative resin layer 33. At that time, plated layer 54 (see FIG. 2) is formed with electroless plated film 51 and electrolytic plated film 53. Moreover, microstripline 26 is formed with first conductive layer 24 and outermost conductive layer (16A) positioned farthest among conductive layers 16 on the first-surface (81F) side of substrate 81; high-frequency substrate portion 27 has outermost conductive layer (16A), first insulative resin layer 23 and first conductive layer 24.

During the above process, the cross-sectional shape of first conductive layer 24 is set to be rectangular, and side surfaces of first conductive layer 24 are positioned substantially parallel to the thickness direction of substrate 81. Upper and side surfaces of first conductive layer 24 are set to be smooth.

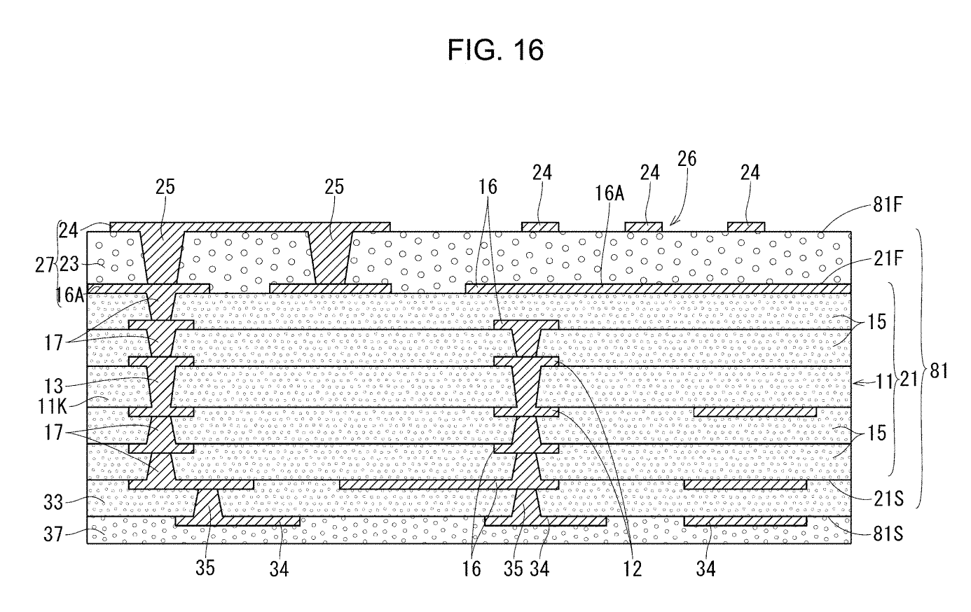

(22) As shown in FIG. 16, solder-resist layer 37 is laminated on second conductive layer 34. Next, photoresist treatment is conducted, making openings (37A) in solder-resist layer 37, and forming pads 38 in second conductive layer 34. Accordingly, printed wiring board 10 shown in FIG. 1 is completed.

The method for manufacturing printed wiring board 10 of the present embodiment is described above. Next, the effects of printed wiring board 10 and its manufacturing method are described.

In printed wiring board 10 of the present embodiment, first conductive layer 24 of microstripline 26 is made up of copper foil 50 and plated layer 54 on copper foil 50. Printed wiring board 10 having such a structure is manufactured by laminating copper foil 50 entirely on first insulative resin layer 23, followed by forming plated layer 54 with a predetermined pattern on copper foil 50, and then by removing copper foil 50 from where no plated layer 54 is formed. According to such a manufacturing method of the embodiment, insertion loss is reduced in a wiring pattern made of first conductive layer 24, thereby lowering signal loss when signals are transmitted through the wiring pattern as described later in [Assessment by Simulation].

### Assessment by Simulation

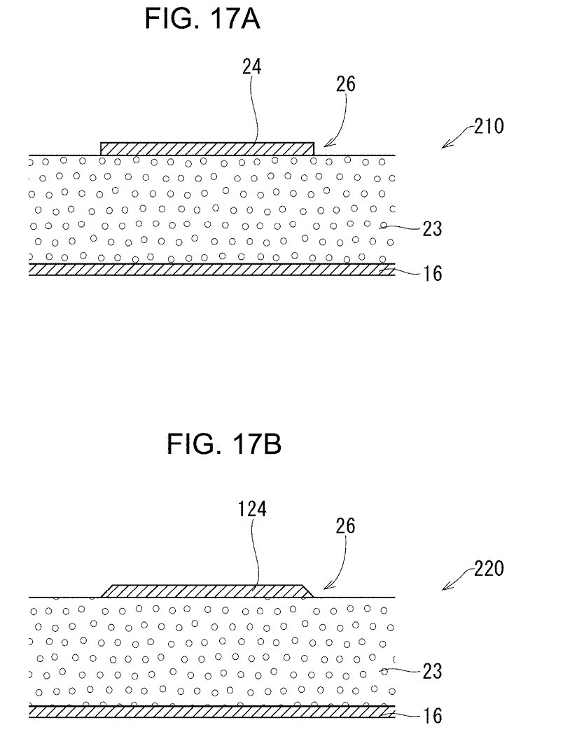

The effect of a reduction in insertion loss in wiring patterns of printed wiring board 10 was assessed by conducting simulation. More specifically, insertion loss in wiring patterns was calculated through simulation conducted on first conductive layers (24, 124) of substrates (210, 220) shown respectively in FIGS. 17A and 17B. Substrates (210, 220) are triple-layered with conductive layer 16, first insulative resin layer 23 and their respective first conductive layers (24, 124). Substrate 210 shown in FIG. 17A was used in test 1, and substrate 220 shown in FIG. 17B was used in test 2. Details of the tests and simulation are as follows.

In simulation, PTFE was used for forming first insulative resin layer 23, and copper was used for forming conductive layer 16 and first conductive layers (24, 124). Insertion loss was calculated using the ratio of the output signal intensity to the input signal intensity in the wiring patterns (first conductive layers (24, 124)). Input signals were set at a frequency of 0˜80 GHz.

Substrate 210 in test 1 corresponds to high-frequency substrate portion 27 in printed wiring board 10 of the embodiment. The thickness and width of each layer in substrate 210 are set as follows: the thickness of conductive layer 16 is 18 μm; the thickness of first insulative resin layer 23 is 127 μm; the thickness of first conductive layer 24 is 18 μm; conductive layer 16 is formed entirely on one surface of first insulative resin layer 23; and the width of first conductive layer 24 is 270 μm.

In substrate 220 of test 2, the cross-sectional shape of first conductive layer 124 is set to be trapezoidal, different from that of first conductive layer 24 of substrate 210. Conductive layer 16 and first insulative resin layer 23 in substrate 220 are the same as those in substrate 210 of test 1. First conductive layer 124 of substrate 220 is formed by laminating a conductive layer entirely on first insulative resin layer 23 and by pattern-etching the conductive layer. In substrate 220, the thickness of first conductive layer 124 is 18 μm, the width of the upper surface (the surface farther from first insulative resin layer 23) of first conductive layer 124 is 260 μm, and the width of the lower surface (the surface closer to first insulative resin layer 23) of first conductive layer 124 is 275 μm.

Thicknesses, widths and the like of first conductive layer 24 of substrate 210 in test 1 and first conductive layer 124 of substrate 220 in test 2 are set so that the wiring resistance will be 50Ω in each of the wiring patterns formed respectively by first conductive layers (24, 124).

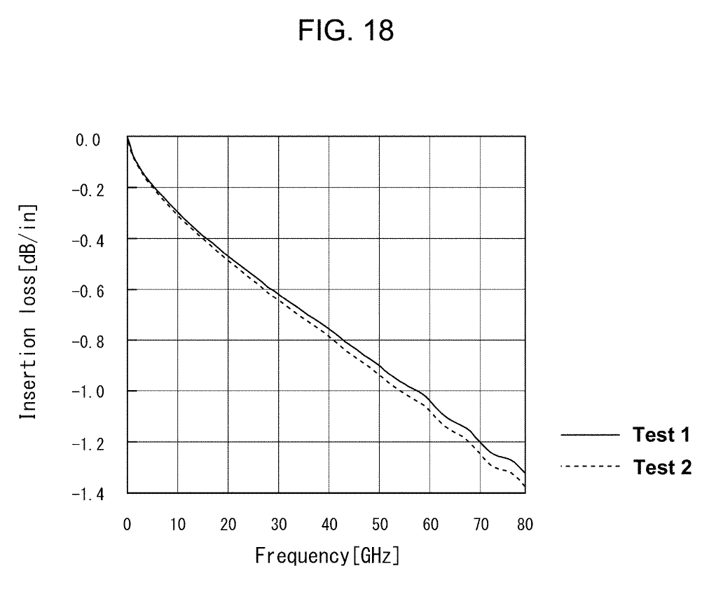

FIG. 18 is a graph showing frequency characteristics of insertion loss in the wiring patterns in tests (1, 2). In the graph, lines going downward indicate an increase in insertion loss. In each of tests (1, 2), it is found that insertion loss increases as the frequency of input signals increases. When test 1 and test 2 are compared, insertion loss is smaller in test 1 than that in test 2 at any frequency band. The difference in insertion loss between test 1 and test 2 is found to be significant in a frequency range of 50 GHz or higher.

As is clear in the test results shown in FIG. 18, it is found that insertion loss is reduced when the cross-sectional shape of a wiring pattern (first conductive layer 24) is rectangular as in substrate 210 of test 1, compared with wiring patterns having a trapezoidal cross-sectional shape such as a wiring pattern (first conductive layer 124) of substrate 220 in test 2. Here, the difference in the cross-sectional shapes of the wiring patterns of substrates (210, 220) (namely, different cross-sectional shapes of first conductive layers (24, 124)) is derived from the difference in processes for forming wiring patterns. In the method for manufacturing printed wiring board 10 according to the embodiment, first conductive layer 24 is formed by forming plated layer 54 with a predetermined pattern on copper foil 50 and then by removing copper foil 50 from where plated layer 54 is not formed. Because of such a process, first conductive layer 24 of the wiring pattern has a rectangular cross-sectional shape. Accordingly, insertion loss is reduced in the wiring pattern.

### OTHER EMBODIMENTS

The present invention is not limited to the above embodiment. For example, the embodiments below are also included in the technological scope of the present invention. Furthermore, any modification is possible for practicing the present invention unless it deviates from the gist of the present invention.

(1) In the above embodiment, an insulative resin layer may further be laminated on first conductive layer 24. In other words, it is an option for first conductive layer 24 not to be the outermost conductive layer of printed wiring board 10.

(2) In the above embodiment, as long as first insulative resin layer 23 has a sufficiently low dielectric constant (Dk) and dielectric loss tangent (Df), the thickness of first insulation layer 23 may be set to be substantially the same as that of interlayer insulative resin layer 15.

(3) In the above embodiment, the thickness of second insulative resin layer 33 is substantially the same as that of interlayer insulative resin layer 15, but their thicknesses may be set different.

(4) In the above embodiment, the thickness of insulative base material (11K) may be the same as or different from the thickness of interlayer insulative resin layer 15. If insulative base material (11K) has a greater thickness, it is an option to connect conductive layers (12, 12) by through-hole conductors that penetrate through insulative base material (11K).

A printed wiring board may have a wiring pattern for a microstripline which is formed on an insulation layer made of a low dielectric resin material. In such a printed wiring board, the wiring pattern is formed by etching a metal layer laminated on an insulation layer, and problems may arise such as greater signal loss when signals are transmitted through the wiring patterns.

A printed wiring board according to an embodiment of the present invention reduces signal loss when transmitting signals through wiring patterns, and another embodiment of the present invention is a method for manufacturing such a wiring board.

A printed wiring board according to an embodiment of the present invention has a base substrate portion formed by alternately laminating a conductive layer and an insulative resin layer; a first insulative resin layer laminated on a first surface, which is either of the upper and lower surfaces of the base substrate portion; a first conductive layer laminated on the first insulative resin layer; and a high-frequency substrate portion has the conductive layer positioned outermost on the first-surface side of the base substrate portion, the first insulative resin layer and the first conductive layer. The first conductive layer includes wiring patterns which, along with a portion forming the high-frequency substrate portion, include microstrip lines, the first insulative resin layer has a dielectric constant of 3.5 or lower and a dielectric loss tangent of 0.005 or lower, and side surfaces of the wiring pattern are positioned to be substantially parallel to the thickness direction of the first insulative resin layer.

A method for manufacturing a printed wiring board according to an embodiment of the present invention includes: forming a base substrate portion by alternately laminating a conductive layer and an insulative resin layer; laminating a first insulative resin layer on a first surface, which is either of the upper and lower surfaces of the base substrate portion; forming a first conductive layer on the first insulative resin layer; and forming a high-frequency substrate portion including portions of the conductive layer positioned outermost on the first-surface side of the base substrate portion, the first insulative resin layer and the first conductive layer. Forming the first conductive layer includes forming wiring patterns which, along with a portion forming the high-frequency substrate portion, include microstrip lines; and forming the wiring pattern includes laminating a metal foil entirely on the first insulative resin layer, forming a plated layer with a predetermined pattern on the metal foil, and removing the metal foil from where no plated layer is formed.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
a base substrate;
a first insulative resin layer laminated on a first surface of the base substrate;
a first conductive layer laminated on the first insulative resin layer,
wherein the base substrate comprises a plurality of conductive layers and a plurality of insulative resin layers, the base substrate, the first insulative resin layer and the first conductive layer include a high-frequency substrate portion comprising a portion of an outermost conductive layer in the base substrate, a portion of the first insulative resin layer and a portion of the first conductive layer, the first conductive layer has a plurality of wiring patterns comprising a plurality of microstrip lines and the portion forming the high-frequency substrate portion, the first insulative resin layer has a dielectric constant of 3.5 or lower and a dielectric loss tangent of 0.005 or lower, and the wiring pattern is formed such that side surfaces of the wiring pattern are substantially parallel to a thickness direction of the first insulative resin layer.

2. A printed wiring board according to claim 1, wherein the base substrate and the first insulative resin layer are formed such that the dielectric loss tangent of the first insulative resin layer is smaller than a dielectric loss tangent of each of the insulative resin layers in the base substrate.

3. A printed wiring board according to claim 1, wherein the base substrate and the first insulative resin layer are formed such that the first insulative resin layer has a thickness that is greater than a thickness of each of the insulative resin layers in the base substrate.

4. A printed wiring board according to claim 1, wherein the first conductive layer is formed such that the plurality of wiring patterns includes a metal foil layer having a thickness of 5 μm or less, and a plated layer formed on the metal foil layer.

5. A printed wiring board according to claim 1, wherein the first conductive layer and the first insulative resin layer are formed such that an interface between the first conductive layer and the first insulative resin layer has a roughness Ra that is set 0.5 μm or smaller.

6. A printed wiring board according to claim 1, wherein the first conductive layer is formed such that the plurality of wiring patterns has a minimum wiring width of at least 75 μm and a minimum value of at least 75 μm for distances between adjacent wirings.

7. A printed wiring board according to claim 1, wherein the first conductive layer is forming an outermost conductive layer.

8. A printed wiring board according to claim 1, wherein the first conductive layer is formed such that the plurality of wiring patterns has upper surfaces and side surfaces that are smooth surfaces.

9. A printed wiring board according to claim 2, wherein the base substrate and the first insulative resin layer are formed such that the first insulative resin layer has a thickness that is greater than a thickness of each of the insulative resin layers in the base substrate.

10. A printed wiring board according to claim 2, wherein the first conductive layer is formed such that the plurality of wiring patterns includes a metal foil layer having a thickness of 5 μm or less, and a plated layer formed on the metal foil layer.

11. A printed wiring board according to claim 2, wherein the first conductive layer and the first insulative resin layer are formed such that an interface between the first conductive layer and the first insulative resin layer has a roughness Ra that is set 0.5 μm or smaller.

12. A printed wiring board according to claim 2, wherein the first conductive layer is formed such that the plurality of wiring patterns has a minimum wiring width of at least 75 μm and a minimum value of at least 75 μm for distances between adjacent wirings.

13. A printed wiring board according to claim 2, wherein the first conductive layer is forming an outermost conductive layer.

14. A printed wiring board according to claim 3, wherein the first conductive layer is formed such that the plurality of wiring patterns includes a metal foil layer having a thickness of 5 μm or less, and a plated layer formed on the metal foil layer.

15. A printed wiring board according to claim 3, wherein the first conductive layer and the first insulative resin layer are formed such that an interface between the first conductive layer and the first insulative resin layer has a roughness Ra that is set 0.5 μm or smaller.

16. A printed wiring board according to claim 3, wherein the first conductive layer is formed such that the plurality of wiring patterns has a minimum wiring width of at least 75 μm and a minimum value of at least 75 μm for distances between adjacent wirings.

17. A printed wiring board according to claim 3, wherein the first conductive layer is forming an outermost conductive layer.

18. A printed wiring board according to claim 4, wherein the first conductive layer and the first insulative resin layer are formed such that an interface between the first conductive layer and the first insulative resin layer has a roughness Ra that is set 0.5 μm or smaller.

19. A method for manufacturing a printed wiring board, comprising:
forming a base substrate comprising a plurality of conductive layers and a plurality of insulative resin layers alternately laminated; and
laminating a first insulative resin layer on a first surface of the base substrate;
forming a first conductive layer on the first insulative resin layer,
wherein the forming of the base substrate, the laminating of the first insulative resin layer and the forming of the first conductive layer include forming a high-frequency substrate portion comprising a portion of an outermost conductive layer in the base substrate, a portion of the first insulative resin layer and a portion of the first conductive layer, and the forming of the first conductive layer includes laminating a metal foil entirely on the first insulative resin layer, forming a plated layer having a pattern on the metal foil, and removing the metal foil from where no plated layer is formed such that the first conductive layer includes a plurality of wiring patterns comprising a plurality of microstrip lines and the portion forming the high-frequency substrate portion.

20. A method for manufacturing a printed wiring board according to claim 19, wherein the first insulative resin layer has a dielectric constant of 3.5 or lower and a dielectric loss tangent of 0.005 or lower.
